(19) United States
(12) Patent Application Publication
(10) Pub. No.: US 2025/0388459 A1
(43) Pub. Date: Dec. 25, 2025

(54) Processing Methods for Wafer-Level Encapsulated MEMS Devices with Stable Cavity Pressure Over Temperature

(71) Applicant: Stathera IP Holdings Inc., Montreal (CA)

(72) Inventors: Riccardo Gatti, Laval (CA); Qing Zhang, Montreal (CA); Anosh Daruwalla, Montreal (CA)

(21) Appl. No.: 19/196,209

(22) Filed: May 1, 2025

Related U.S. Application Data
(60) Provisional application No. 63/662,314, filed on Jun. 20, 2024.

(51) Int. Cl. B81B 7/00; B81C 1/00

(52) U.S. Cl. CPC B81B 7/0038; B81C 1/00285; B81B 2201/0271; B81B 2203/03; B81B 2203/0307; B81B 2203/0315; B81B 2203/04; B81B 2207/056; B81B 2207/07; B81B 2207/095; B81C 2201/013; B81C 2201/0176; B81C 2201/0181; B81C 2203/0109

(57) ABSTRACT

Encapsulated MEMS devices and methods of fabrication with wafer-level fabrication processes are described which address small molecule diffusion into hermetically sealed cavities. In some configurations a small molecule barrier layer, or hydrogen barrier layer, is formed during a back-end-of-the-line (BEOL) processing over a cap wafer including a planarized surface formed during a via reveal griding operation. In some configurations a small molecule barrier layer is not formed over the planarized surface during BEOL processing in order to allow an escape path for small molecules. In some configurations a small molecule barrier layer, or hydrogen barrier layer, is formed on a bottom side of a cap wafer prior to bonding the cap wafer to a device wafer during wafer-level fabrication.

### RELATED APPLICATIONS

This application claims the benefit of priority from U.S. Provisional Patent Application Ser. No. 63/662,314 filed on Jun. 20, 2024, the full disclosure of which is incorporated herein by reference.

### BACKGROUND

### Field

Embodiments described herein relate to microelectromechanical systems (MEMS).

### Background Information

Microelectromechanical systems (MEMS) are small integrated devices or systems that combine electrical and mechanical components. The components can range in size from the sub-micrometer level to the millimeter level, and there can be any number, from one, to a few, to potentially thousands or millions, in a particular system. Some MEMS structures, in particular MEMS resonators, are hermetically sealed within low-pressure cavities to ensure consistent operation in different environments and temperature ranges. However, materials such as silicon and silicon dioxide commonly used in wafer-level fabrication of MEMS structures can be permeable to small gas molecules such as hydrogen and helium, potentially leading to changes in the internal pressure of the cavity with temperature.

### SUMMARY

Encapsulated MEMS devices and methods of fabrication with wafer-level fabrication processes are described. In an embodiment, a wafer-level MEMS fabrication process includes patterning a support wafer to form a plurality of cavities and anchors, bonding a device wafer to the support wafer, and patterning the device wafer to include a plurality of resonator elements over the plurality of anchors, and plurality of electrodes laterally adjacent to the resonator elements. A cap wafer is then bonded to (e.g., directly to) the device wafer, the cap wafer including a plurality of isolation trenches extending partially through a thickness of the cap wafer and defining a corresponding plurality of vias. The vias in accordance with embodiments can assume a variety of shapes and be functionalized for different applications such as via interconnects, out-of-plane via drive electrodes, out-of-plane via sense electrodes, and via bias electrodes. The isolation trenches may additionally isolate functionalized vias from other bulk regions of the cap wafer, as well as from adjacent functionalized vias from one another. A thickness of the cap wafer is then reduced, for example with a grinding operation, to expose the plurality of isolation trenches. Following the isolation trench reveal, or via reveal, operation further back-end-of-the-line (BEOL) processing may be performed, which may or may not include the formation of a small molecule barrier layer, also referred to herein as a hydrogen barrier layer. In an embodiment, a hydrogen barrier layer is deposited directly on a planarized surface of a top side of the cap wafer and top sides of the plurality of isolation trenches following the via reveal, or isolation trench reveal, operation. For example, this may be performed using suitable techniques such as chemical vapor deposition (CVD) or physical vapor deposition (PVD) techniques. In some embodiments a physical vapor sputtering technique in a hydrogen-free environment is utilized in order to avoid the introduction of hydrogen and other small molecules. The hydrogen barrier layer may extend entirely across the isolation trenches. In other embodiments, a hydrogen barrier layer is not formed and instead a hydrogen-permeable dielectric layer, such as silicon oxide, is deposited directly on a planarized surface of a top side of the cap wafer and top sides of the plurality of isolation trenches. Optionally, a hydrogen barrier layer can be formed over the hydrogen-permeable dielectric layer (e.g., as a top-most passivation layer) after performing an outgassing operation to drive off residual hydrogen from the underlying layer(s). In some embodiments, a hydrogen barrier layer is formed on bottom sides of the isolation trenches prior to bonding the cap wafer to the device wafer.

In an embodiment, a MEMS device includes a top side hydrogen barrier layer. In such an embodiment, the MEMS device includes a device layer, a cap substrate including a bottom side that is bonded to the device layer and a top side, and a cavity between the device layer and the cap substrate. An isolation trench may extend through the cap substrate from the top side to the bottom side, and laterally surround a via of the cap substrate. In an embodiment, the top side of the cap substrate and a top side of the isolation trench form a planarized surface, and a hydrogen barrier layer is directly on the planarized surface forming the top side of the cap substrate and the top side of the isolation trench. The hydrogen barrier layer may extend entirely across the isolation trenches. The hydrogen barrier layer may be for formed of materials such as aluminum, copper, titanium, nickel, gold, chromium, molybdenum, titanium nitride, metal silicide, polysilicon, silicon nitride, aluminum nitride, aluminum oxide, and silicon carbide. Any other metal that is generally used for metallization purposes can be used. The hydrogen barrier layer may also be electrically insulating to avoid shorting between vias, and be formed of material such as silicon nitride, aluminum nitride, aluminum oxide, and silicon carbide.

The MEMS device may further include an opening in the hydrogen barrier layer that exposes the via, an electrical contact terminal within the opening an in direct contact with the via, and a hydrogen-permeable passivation layer such as silicon oxide directly on top of the electrical contact terminal and over the hydrogen barrier layer. The isolation trenches and vias may be arranged in a variety of locations relative to the cavity and resonator element. The vias in accordance with embodiments can assume a variety of shapes and be functionalized for different applications such as via interconnects, out-of-plane via drive electrodes, out-of-plane via sense electrodes, and via bias electrodes. For example, the isolation trench can be directly over a resonator element of the device layer. In such an arrangement the via can function as an out-of-plane via drive electrode or out-of-plane via sense electrode that is at least partially (directly) over the resonator element. As another example, the via can be bonded to an in-plane drive electrode or an in-plane sense electrode of the device layer that is laterally adjacent to the resonator element of the device layer. In such an embodiment, the via can function as a via interconnect to the in-plane drive electrode or in-plane sense electrode. As yet another example, the via can be bonded to the resonator element. In such an arrangement the via may function as a via bias electrode and/or as a bulk region of the device layer to provide mechanical support to the resonator element.

In an embodiment, a MEMS device does not necessarily include a top side hydrogen barrier layer. In such an embodiment, the MEMS device includes a device layer, a cap substrate including a bottom side that is bonded to the device layer and a top side, and a cavity between the device layer and the cap substrate. An isolation trench may extend through the cap substrate from the top side to the bottom side, and laterally surround a via of the cap substrate. In an embodiment, the top side of the cap substrate and a top side of the isolation trench form a planarized surface, and a first hydrogen-permeable dielectric layer is directly on the planarized surface forming the top side of the cap substrate and the top side of the isolation trench. An opening exists in the first hydrogen-permeable dielectric layer that exposes the via, an electrical contact terminal within the opening an in direct contact with the via, and a second hydrogen-permeable dielectric layer directly on top of the electrical contact terminal and the first hydrogen-permeable dielectric layer. The electrical contact terminal may be formed of one or more layers and materials. The isolation trenches and vias may arranged in a variety of locations relative to the cavity and resonator element. For example, the isolation trench can be directly over a resonator element of the device layer. As another example, the via can be bonded to an in-plane drive electrode or in-plane sense electrode of the device layer that is laterally adjacent to the resonator element of the device layer. As yet another example, the via can be bonded to the resonator element.

In an embodiment, a MEMS device includes a bottom side hydrogen barrier layer. In such an embodiment, the MEMS device includes a device layer, a cap substrate including a bottom side that is bonded to the device layer and a top side, and a cavity between the device layer and the cap substrate. An isolation trench may extend through the cap substrate from the top side to the bottom side, and laterally surround a via of the cap substrate. In an embodiment, a hydrogen barrier layer is formed on a bottom side of the isolation trench that faces the cavity. The isolation trenches and vias may be arranged in a variety of locations relative to the cavity and resonator element. For example, the isolation trench can be directly over a resonator element of the device layer. As another example, the via can be bonded to an in-plane drive electrode or in-plane sense electrode of the device layer that is laterally adjacent to the resonator element of the device layer. As yet another example, the via can be bonded to the resonator element. A bottom side of the isolation trench may also be recessed a depth within a contour of the bottom side of the cap substrate, and the hydrogen barrier layer may be directly on the isolation trench and at least partially fill the recessed depth. In accordance with embodiments the bottom side hydrogen barrier layer can be combined with any of the BEOL structures described herein, which may or may not also include a hydrogen barrier layer.

### BRIEF DESCRIPTION OF THE DRAWINGS

FIG. 1A is an isometric view illustration of a MEMS device with rectangular resonator element in accordance with an embodiment.

FIGS. 1B-1C are isometric view illustrations of a MEMS device circular resonator element in accordance with an embodiment.

FIGS. 2A-2D are schematic cross-sectional side view illustrations of a wafer-level fabrication processes in accordance with an embodiment.

FIGS. 3A-3D are schematic cross-sectional side view illustrations of a wafer-level fabrication processes of a cap wafer in accordance with an embodiment.

FIG. 4 is a schematic cross-sectional side view illustration of a capacitively-transduced MEMS device and cavity structure with a top side hydrogen barrier layer in accordance with an embodiment.

FIG. 5 is a schematic cross-sectional side view illustration of a piezoelectric transduction MEMS device and cavity structure with a top side hydrogen barrier layer in accordance with an embodiment.

FIGS. 6A-6F are close-up schematic cross-sectional side view illustrations of a BEOL process sequence with top side hydrogen barrier layer in accordance embodiments.

FIG. 7 is a close-up schematic cross-sectional side view of a BEOL structure with a top side hydrogen barrier layer in accordance with an embodiment.

FIG. 8 is a close-up schematic cross-sectional side view of a BEOL structure without a top side hydrogen barrier layer in accordance with an embodiment.

FIG. 9 is a schematic cross-sectional side view illustration of a capacitively-transduced MEMS device and cavity structure with a top side hydrogen barrier layer of FIG. 7 in accordance with an embodiment.

FIG. 10 is a schematic cross-sectional side view illustration of a capacitively-transduced MEMS device and cavity structure without a top side hydrogen barrier layer of FIG. 8 in accordance with an embodiment.

FIG. 11 is a graph illustrating experimental data of cavity pressure inferred from resonator quality factor for MEMS devices of FIGS. 9-10 before and after heating.

FIG. 12 is a schematic cross-sectional side view illustration of a capacitively-transduced MEMS device and cavity structure with a bottom side hydrogen barrier layer in accordance with an embodiment.

FIGS. 13A-13C are schematic cross-sectional side view illustrations of a wafer-level fabrication processes of a cap wafer including a bottom side hydrogen barrier layer in accordance with an embodiment.

### DETAILED DESCRIPTION

Embodiments describe encapsulated MEMS devices and methods of fabrication. In particular, wafer-level fabrication processes are described that provide wafer-level packaged (WLP) and encapsulated MEMS devices that may achieve mTorr cavity pressures stable over temperature. For example, cavity pressures as low as 0.001-10.00 mTorr, can be maintained over temperature ranges such as room temperature to 300° C., or higher.

The wafer-level fabrication processes in accordance with embodiments may include separate front-end-of-the-line (FEOL) fabrication sequences for a support/handle wafer, MEMS device wafer and a cap wafer. The MEMS wafer may have a device (e.g., resonator) that is free to move (is released) and the cap wafer can include through vias (e.g., silicon vias) to allow electric routing to electrodes within the cavity. The vias are defined by isolation trenches, which may include an oxide liner layer material (e.g., silicon oxide). The vias in accordance with embodiments can assume a variety of shapes and be functionalized for different applications such as via interconnects, out-of-plane via drive electrodes, out-of-plane via sense electrodes, via bias electrodes, and/or as a bulk region of the device layer to provide mechanical support to a MEMS (e.g., resonator) element. The cap wafer with vias is then bonded to the MEMS device wafer, for example with silicon-silicon fusion bonding at elevated temperature and specified pressure to define the cavity where the resonator element is free to move and additionally hermetically seal the cavity at a specified pressure. Lower pressures can minimize air resistance and reduce damping of the mechanical structure (e.g., resonator element) and increase the qualify factor (Q-factor). This is then followed by a grinding and polishing operation where the vias and isolation trenches are revealed along a planarized surface. Further back-end-of-the-line (BEOL) processing can then proceed, such as the formation of a passivation layer stack(s), electrical contact terminals to the vias (e.g., to the via interconnects, out-of-plane via drive electrodes and sense electrodes, via bias electrodes, etc.), and metal routing.

In one aspect it has been observed that an oxide liner within the isolation trenches can offer a solid-state diffusion path for small molecules such as hydrogen, helium, etc. into the low-pressure cavity. It has additionally been observed that various BEOL layers such as oxide passivation layers can act as a source of small molecules. More specifically, it has been observed that the passivation layers outgas at elevated temperatures (especially when deposited with CVD processes where chemical by-products can remained trapped in the film), which poses a risk of cavity pressure increase and Q-factor reduction if the small molecules diffuse into the cavity.

It has been observed that outgassing from such passivation layers can be particularly problematic when the isolation trenches are formed after bonding of the cap wafer to the MEMS wafer, and a surface oxide layer is formed over the cap wafer when forming the oxide liner. In accordance with some embodiments a small molecule barrier layer, also referred to herein as a hydrogen barrier layer, is formed directly on the planarized surface of the cap wafer created by a via reveal operation during a wafer-level fabrication sequence. In this manner, small molecules from the BEOL layers are blocked from diffusing into the isolation trenches and cavities. Furthermore, a potential small molecule outgassing source associated with surface oxidation of the cap wafer can be avoided. Suitable small molecule barrier layer (i.e., hydrogen barrier layer) materials may include metals or alloys of metals including aluminum, copper titanium, nickel, gold, chromium, molybdenum, titanium nitride, metal silicides, polysilicon and/or dielectric materials such as silicon nitride, aluminum nitride, aluminum oxide, and silicon carbide. Any other metal that is generally used for metallization purposes can be used. In some instances, semiconductor materials (silicon, germanium, etc.) can be used to form constituent structures of the hydrogen barrier layer.

In accordance with other embodiments, it has also been observed that in some instances a hydrogen barrier layer can have the unintentional effect of trapping small molecules within the cavity. In some embodiments a hydrogen barrier layer is not formed over the isolation trenches in order to allow small molecule diffusion away from the isolation trenches, and not confine the outgassed molecules. In accordance with other embodiments a hydrogen barrier layer is provided on a bottom side of the via isolation trenches to mitigate small molecule diffusion into the cavities. Such a configuration may be made possible with the wafer-level fabrication processes described herein, and can provide a barrier to small molecule outgassing from the BEOL layers as well as from the isolation trench oxide liners and into the cavity. The bottom side hydrogen barrier layer can additionally be combined with other top side BEOL structures describe herein, with or without a hydrogen barrier layer over the isolation trenches.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

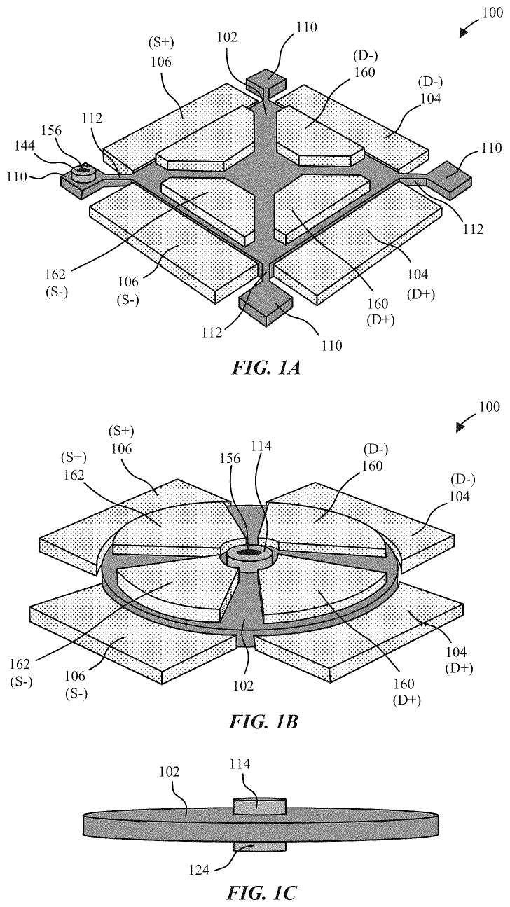

Referring now to FIG. 1A, an isometric view illustration is provided of a MEMS device 100 with rectangular resonator element in accordance with an embodiment. As depicted, the square resonator element 102 may be part of a capacitively-transduced Lamé mode resonator including a pair of in-plane drive electrodes 104 denoted by D+/D− and a pair of in-plane sense electrodes 106 denoted by S+/S−, disposed around its periphery whilst the resonator element 102 itself is direct current (DC) biased through an electrical contact terminal 156 at one or more anchors 110. In this instance connected to corners of the resonator element 102 with tethers 112. As will become more apparent in the following description the electrical contact terminal 156 can connect to the anchor through a via interconnect 144. Via interconnects can similarly be integrated for connecting with the various sense and drive electrodes.

In operation, the two in-plane drive electrodes 104 are used to provide two drive signals that are 180° out of phase, as denoted D+/D−. Another set of in-plane sense electrodes 106, denoted S+/S−, are used to collect the two out of phase output signals and recombine them. A bias voltage can additionally be provided to the resonator element 102 through an electrical contact terminal 156. Typically, this would be used for frequency tuning.

The MEMS device 100 in accordance with embodiments may additionally include out-of-plane via drive electrodes 160 and out-of-plane via sense electrodes 162. For example, the out-of-plane via drive electrodes 160 and out-of-plane via sense electrodes 162 can be positioned over a top surface of the resonator element 102 and separated by a gap distance (such as 0.05-2.0 microns) for capacitive transduction of the resonator element 102. Similar to the in-plane drive electrodes 104 and in-plane sense electrodes 106, the out-of-plane via drive electrodes 160 and out-of-plane via sense electrodes 162 can be utilized to drive and collect out of phase signals and recombine them.

Rather than tethering the resonator element 102 to anchors, the resonator element 102 can be supported by centrally located anchors. FIGS. 1B-1C is an isometric view illustration of a MEMS device circular resonator element 102 in accordance with an embodiment. In interest of clarity the various sense and drive electrodes are not illustrated in FIG. 1C. As shown, the resonator element 102 can be supported by one or more anchors 114, 124 on a top and/or bottom side of the resonator element 102. Similar to the capacitively-transduced resonator depicted in FIG. 1A, the capacitively-transduced resonator depicted in FIG. 1B includes a pair of in-plane drive electrodes 104 denoted by D+/D− and a pair of in-plane sense electrodes 106 denoted by S+/S− disposed around its periphery whilst the resonator element 102 itself is DC biased through one or more anchors 114. The one or more anchors 114 may be physically connected with the resonator element 102 to provide physical support, and optionally function as a DC bias electrode. The one or more anchors 124 may also be physically connected with the resonator element 102 to provide physical support. Similar to FIG. 1A, out-of-plane via drive electrodes 160 and out-of-plane via sense electrodes 162 may optionally be included above the resonator element 102 for out-of-plane driving and sensing.

It is to be appreciated that the resonator structures illustrated in FIGS. 1A-1B are simplified illustrations of MEMS devices 100 in accordance with embodiments that include resonator elements 102 that are suspended within a hermetically sealed cavity maintained at low pressure. Furthermore, the figures are not necessarily drawn to scale. Embodiments are not limited to these specific structures and are applicable to a variety of MEMS devices, such as any bulk acoustic wave (BAW) or surface acoustic wave (SAW) resonator, etc. Different configurations with different electrode arrangements may be implemented without departing from the embodiments. Embodiments described herein may also be applicable to piezoelectrically-transduced resonators.

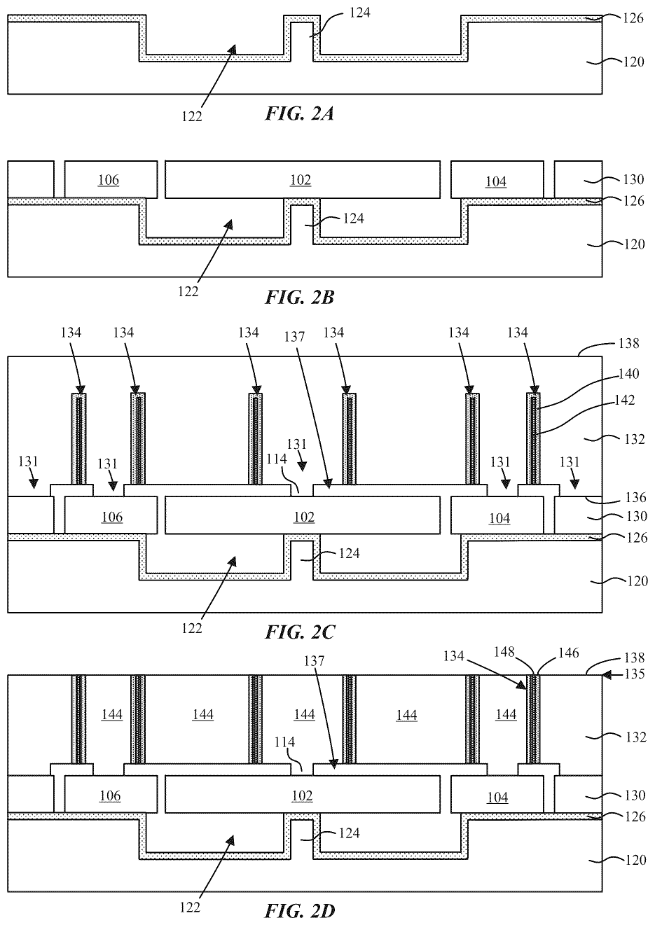

FIGS. 2A-2D are schematic cross-sectional side view illustrations of a wafer-level fabrication processes in accordance with embodiments. As shown in FIG. 2A, the processing sequence can begin with a support substrate 120, which can be a silicon wafer at this stage. The silicon wafer may be patterned to include a lower cavity 122, e.g., 5-50 μm recess, and optionally an anchor 124. An insulator layer 126, such as silicon oxide, may be formed (including grown or deposited) over the top side (top surface) of the support substrate 120 to provide electrical insulation from subsequently bonded layers. A device layer 130 may then be bonded to the support substrate 120, for example with fusion bonding a silicon-silicon oxide interface, as shown in FIG. 2B. The device layer 130 may also be a silicon wafer, which may be pre-processed to include various MEMS structures or processed after wafer bonding. Exemplary MEMS structures include resonators, temperature sensors, humidity sensors, gas sensors, accelerometers, etc. In the particular embodiment illustrated the device layer 130 be approximately 5-100 μm thick, and is patterned to include a resonator element 102 that is supported by anchor 124, in-plane drive electrodes 104 and in-plane sense electrodes 106, for example as illustrated in FIG. 1B. Alternatively, the device layer 130 can include tethers 112 and anchors 110, for example as illustrated in FIG. 1A.

A cap substrate 132 (e.g., patterned silicon wafer) can then be bonded to (e.g., directly to) the device layer 130, such as with fusion bonding to create silicon-silicon bonds. As shown, a patterned contour can be formed in the bottom side 136 (bottom surface) of the cap substrate 132 to include a plurality of mesas 131, inclusive of optional anchor 114. Some mesas 131 may be bonded to the device layer 130, while patterned areas between mesas 131 may be positioned over the resonator element 102 to define area for out-of-plane drive electrodes or sense electrodes. The space between the bottom surface of the cap substrate 132 and device layer 130 can form an upper cavity 137, where the resonator element 102 is hermetically sealed in the cavity volume defined by the upper cavity 137 and lower cavity 122. The height of the upper cavity 137 defines the out-of-plane transduction gap.

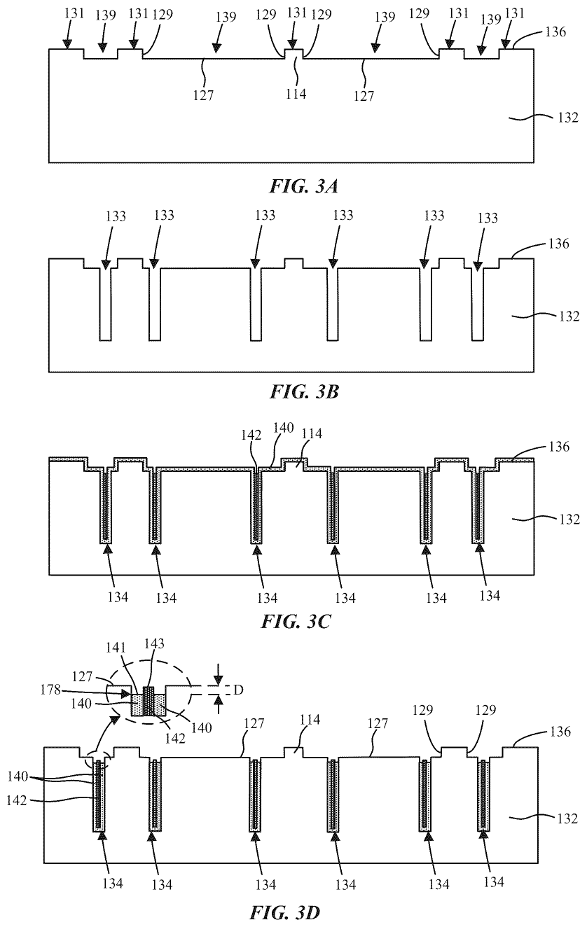

Still referring to FIG. 2C, a plurality of isolation trenches 134 can also be formed in the bottom side 136 of the cap substrate 132 and extend at least partially through a thickness of the cap substrate toward a top side 138 of the cap substrate. Referring briefly to FIGS. 3A-3D, the isolation trenches 134 can be formed in the cap substrate 132 prior to being bonded to the device layer. Each isolation trench 134 may be partially or completely filled with a liner layer 140, such as silicon oxide, and may optionally be filled with a filler material 142, which can by anything conformal such as polysilicon, tetraethyl orthosilicate (TEOS)-oxide grown film, etc. A grinding (and polishing) operation may then be performed to reduce a thickness of the cap substrate 132 and reveal the isolation trenches 134 as shown in FIG. 2D. Reveal of the isolation trenches 134 can also be considered a via reveal operation where vias (e.g., silicon vias) are defined by a contour of laterally surrounding isolation trenches 134. In accordance with embodiments, the grinding operation creates a planarized surface 135 formed of (and spanning) the top side 138 of the cap substrate 132 and the top side of the isolation trenches 134 formed of the top side 146 of the liner layer 140 and top side 148 of the optional filler material 142.

At this stage BEOL processing can be formed over the planarized surface 135 to provide electrical routing, passivation, and optionally the formation of a hydrogen barrier layer. Further processing may then be formed, such as bonding to an integrated circuit wafer and/or singulation of multiple MEMS devices from the stacked wafer structure.

Referring now to FIGS. 3A-3D schematic cross-sectional side view illustrations are provided of a wafer-level fabrication processes of a cap wafer in accordance embodiments. The illustrated process flow begins with a cap substrate 132, which may be a silicon wafer. A pattern of recesses 139 can be formed in the bottom side 136 of the cap substrate 132 to form a plurality of mesas 131. While straight sidewalls 129 are illustrated, it is to be appreciated that the sidewalls 129 may be angled, and may be faceted along specific crystal planes depending upon etching technique/composition and crystal structure and orientation of the cap substrate 132, or may be smeared, as in the case of a local oxidation of silicon (LOCOS) process. The mesas 131 may be utilized to make contact with the device layer, such as during bonding described above with regard to FIG. 2C. Mesas 131 may include an optional anchor 114. As shown in FIG. 3B, isolation trench openings 133 are then etched into the cap substrate 132. The isolation trench openings 133 may be etched into recess bottom surfaces 127 of the recesses 139. A liner layer 140 material such as silicon oxide can be initially grown or deposited along sidewalls of the trench openings 133. This can be followed by deposition or growth of a filler material 142, such as polysilicon, TEOS-oxide grown film, etc., to completely fill the trench openings 133 as shown in FIG. 3C in order to prevent cracks and particle contamination within the trench openings 133 during downstream processing (e.g., chemical mechanical polishing slurry). The liner layer 140 may be formed over the entire bottom side 136 of the cap substrate 132. For example, the liner layer 140 may be formed using a thermal oxidation technique over the exposed surface of the cap substrate 132 (wafer) to form a uniform silicon oxide layer that forms an outline of the exposed topography. It is to be appreciated that while topographies of various patterned surfaces are illustrated as being right angles, that this can be for ease of illustration and that various sidewalls may be angled or tapered. For example, the isolation trench openings 133 can be slanted or tapered to avoid pinching of the lining layer 140 at the bottom surface 127, and avoid the formation of keyholes, voids and partial filling with the filler material 142. The filler material 142 may be chosen to have a highly conformal CVD process, in order to ensure a complete fill without introducing keyholes (thus making small molecule diffusion into the cavity easier). The filler material 142 may be polysilicon material in an embodiment, though it is possible other materials could also be utilized such as TEOS-oxide grown film, etc. The filler material 142 may be deposited to fill a specified height of the trench openings 133, with consideration of additional thickness of the liner layer 140.

The liner layer 140 and the filler material 142 may then be removed from the bottom side 136 of the cap substrate 132 as shown in FIG. 3D, inclusive of the recess bottom surfaces 127 and sidewalls 129 of the mesas, leaving behind the isolation trenches 134 and the exposed bottom side 136 on the crystal silicon of cap substrate 132. For example, a suitable etching technique selective to filler material 142 first, and then liner layer 140 may be employed. Batch wet processes may be preferrable for higher processing throughput, such as TMAH, in case polysilicon is used as filler material 142, and HF for silicon oxide as the liner layer 140. As shown in FIG. 3D, the liner layer 140 and filler material 142 may substantially fill the isolation trench openings 133, though the topographies of the liner layer 140 and filler material 142 may be different due to different etch selectivities of the etchants for the different materials. In the exemplary embodiment illustrated, the bottom surfaces 141, 143 of the liner layer 140 and filler material 142, respectively, forming the bottom sides 178 of the isolation trenches 134 can be optionally recessed to different depths (D) below the bottom surfaces 127 of the recesses 139. It is imperative the bottom surface 143 of the filler material 142 does not exceed the topography of the bonding plane defined by bottom side 136 so as to enable good direct bonding. Such a configuration may be a result of the fabrication sequence. Alternatively, both bottom surfaces 141, 143 can be flush with one another, and optionally flush with the bottom surfaces 127 of the recesses 139. This partially processed cap substrate 132 (wafer) can then be bonded to a device layer 130 as shown in the wafer-level process flow of FIG. 2C and further processed as described herein.

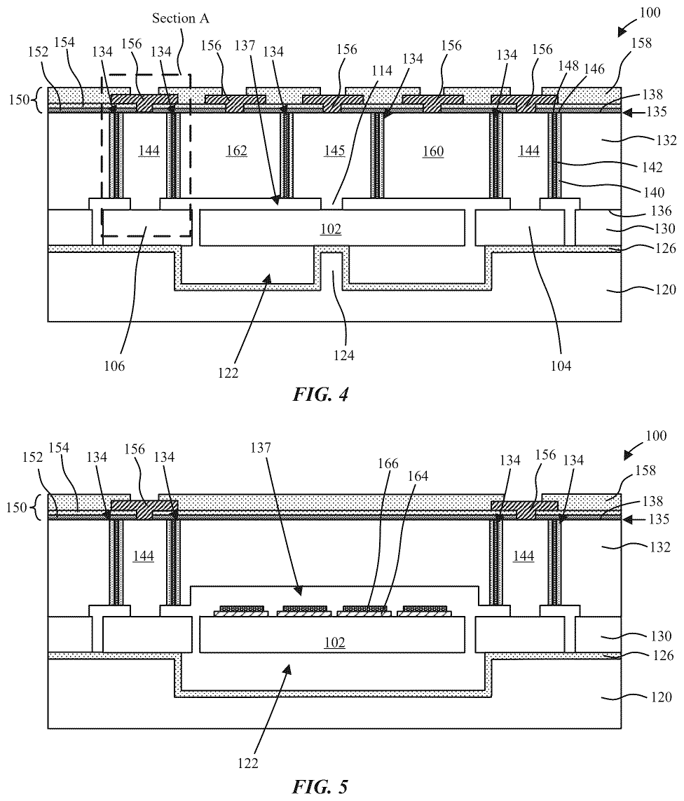

FIG. 4 is a schematic cross-sectional side view illustration of a capacitively-transduced MEMS device 100 and cavity structure with a top side hydrogen barrier layer in accordance with an embodiment. As shown, the MEMS device 100 includes a device layer 130, a cap substrate 132 including a bottom side 136 that is bonded to the device layer 130 and a top side 138. An upper cavity 137 is located between the device layer 130 and the cap substrate 132. The upper cavity 137 may have the same dimensions as the recesses 139 described with regard to FIG. 3A. Additionally, a plurality of isolation trenches 134 extends through the cap substrate from the top side 138 to the bottom side 136 and laterally surrounds corresponding vias (e.g., via interconnect 144, out-of-plane via drive electrode 162, out-of-plane via sense electrode 160, via bias electrode 145, etc.) of the cap substrate 132. As a result of the wafer-level processing sequence illustrated in FIGS. 2A-2D, the top side 138 of the cap substrate 132 and a top side of the isolation trench 134 form a planarized surface 135, and more specifically top side 146 of the liner layer 140 and top side 148 of the optional filler material 142. A BEOL structure 150 can then be formed over the planarized surface 135.

In the particular embodiment illustrated in FIG. 4, the BEOL structure 150 includes a hydrogen barrier layer 152 directly on the planarized surface 135 forming the top side 138 of the cap substrate 132 and the top side of the isolation trench 134. The hydrogen barrier layer 152 may be globally deposited and span over the planarized surface except for where patterned to expose the vias for electrical contact terminals 156. In accordance with embodiments, deposition of the hydrogen barrier layer 152 may be performed after a small molecule evacuation bake at elevated temperature, for example up to 1,100° C., to seal the oxide liner layer 140. This may prevent the ingress of small molecules from subsequent BEOL processes. In an embodiment the hydrogen barrier layer 152 is deposited utilizing a hydrogen-free deposition process such as physical vapor sputtering to minimize the change of small molecule ingress.

The hydrogen barrier layer 152 may be a single layer or multiple-layer stack including one or more layers of aluminum, copper, titanium, nickel, gold, chromium, molybdenum, titanium nitride, metal silicide, polysilicon, silicon nitride, aluminum nitride, aluminum oxide, or silicon carbide. Any other metal that is generally used for metallization purposes can be used. As is known to a skilled reader, if the hydrogen barrier layer 152 is a multiple-layer stack which includes one or more metals, the first layer (deposited on planarized surface 135) must be both a dielectric material and a hydrogen barrier material but not a metal, for example SiN, silicon carbide, to avoid shorting. The hydrogen barrier layer 152 may also be formed of a dielectric material to avoid shorting. For example, the hydrogen barrier layer 152 may be formed of one or more layers of silicon nitride, aluminum nitride, aluminum oxide, or silicon carbide. In an embodiment, the hydrogen barrier layer 152 is a single layer of silicon nitride formed by physical vapor sputtering. In an alternative embodiment, the hydrogen barrier layer 152 is formed by a CVD process which introduces as little hydrogen as possible, to reduce subsequent out-gassing.

Prior to forming the electrical contact terminals, a hydrogen-permeable passivation layer 154 may be formed over the hydrogen barrier layer 152. The hydrogen-permeable passivation layer 154 may be formed of a suitable dielectric material such as silicon oxide used for BEOL structures to provide electrical insulation, film quality, and deposition rate. In particular, when the hydrogen barrier layer 152 is formed of a high-stress nitride that cannot be deposited thick enough to provide sufficient dielectric insulation of metal traces, adding the optional hydrogen-permeable passivation layer 154 can provide improved dielectric insulation. Openings may then be formed through the hydrogen barrier layer 152 and the optional hydrogen-permeable passivation layer 154 to expose the vias to be functionalized, followed by deposition of electrical contact terminals 156. For example, the contact terminals can be formed on the silicon via that become via interconnects 144, or out-of-plane via drive electrodes 160, out-of-plane via sense electrodes 162, or via bias electrodes 145. The electrical contact terminals 156 may be formed of one or more layers including various metal layers and alloys thereof, polysilicon, etc. Selection of materials may additionally depend upon doping concentrations cap layer. For example, a first liner layer of heavily doped polysilicon (e.g., intrinsically doped polysilicon, ISDP) can first be deposited directly onto n-type silicon via interconnects to avoid creating a p-n junction. This can be followed by depositing one or more bulk metal layers, such as copper, gold, etc. An intermediate polysilicon layer may not be necessary for making electrical contact with p-type silicon. A variety of arrangements are possible.

Additional BEOL processing can be performed following the formation of the electrical contact terminals 156, such as the formation of another hydrogen-permeable passivation layer 158 (e.g., silicon oxide) directly on top of the electrical contact terminal and over the hydrogen barrier layer 152.

As shown in FIG. 4 the isolation trenches 134 can be located directly (vertically) over the resonator element 102 and define vias located over the resonator element 102, such as a via bias electrode 145, out-of-plane via drive electrodes 160, or out-of-plane via sense electrodes 162. The isolation trenches 134 can also be located outside a periphery, or outside the footprint, of the resonator element 102. For example, the isolation trenches 134 can laterally surround via interconnects 144 that are bonded to the in-plane drive electrodes 104 and/or in-plane sense electrodes 106 of the device layer 130.

Thus, the resonator structure depicted in FIG. 4 includes at least one out-of-plane drive electrode 160 for actuation of the resonator element 102, at least one out-of-plane sense electrode 162 for sensing the resonator element 102, at least one in-plane sense electrode 106 for sensing the resonator element 102, and at least one in-plane drive electrode 104 for actuation of the resonator element 102. In this example, the electrodes can be electrically connected with the corresponding electrical contact terminals 156 either directly or through via interconnects 144, and a low-pressure, hermetically sealed cavity may be formed to contain the resonator element 102. Additionally, the via bias electrode 145 including anchor 114 may be connected to a DC bias source independent of the drive and sense electrodes. Different configurations with different electrode arrangements may be implemented.

FIG. 5 is a schematic cross-sectional side view illustration of a piezoelectrically transduced MEMS device 100 and cavity structure with a top side hydrogen barrier layer in accordance with an embodiment. The BEOL structure 150 illustrated in FIG. 5 is similar to that illustrated in FIG. 4, though this is not required and any BEOL structure 150 can be utilized. More specifically, FIG. 5 illustrates piezoelectric transduction of a resonator element 102 rather than capacitive transduction. In such an embodiment, the piezoelectric drive electrodes and piezoelectric sense elections can be formed of stacked piezoelectric layers 164 and metal layers 166 on the resonator element 102 and connected to via interconnects 144 and corresponding electrical contact terminals 156, for example over the tethers 112 illustrated in FIG. 1A. Thus, the various hydrogen barrier layer sealing structures described herein can be implemented with both piezoelectric transduction MEMS devices and capacitive transduction MEMS devices.

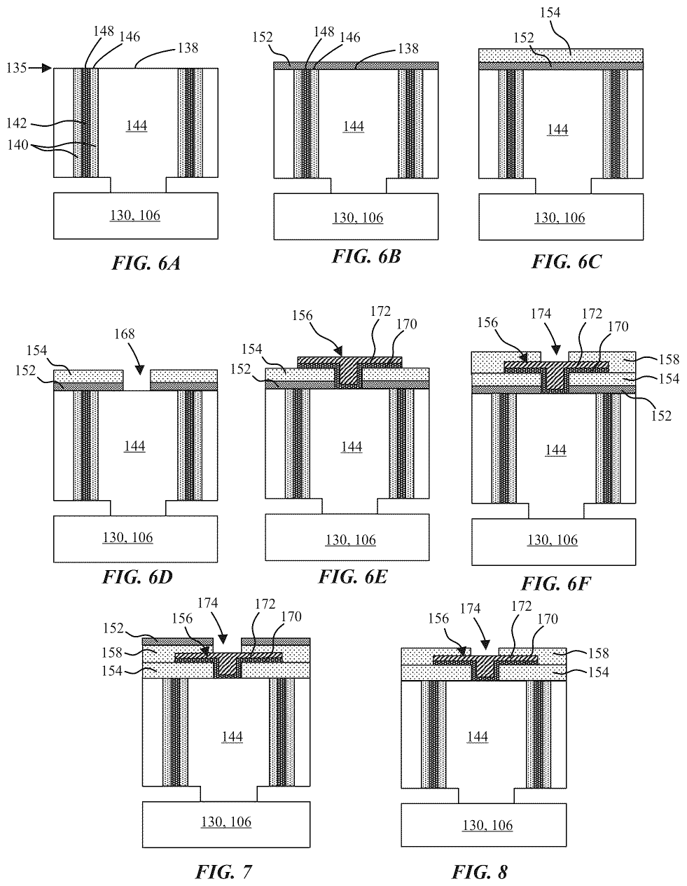

FIGS. 6A-6F are close-up schematic cross-sectional side view illustrations of a BEOL process sequence with top side hydrogen barrier layer in accordance embodiments. Specifically, FIGS. 6A-6F are taken along Section A of FIG. 4. While FIGS. 6A-6F are illustrated with regard to the via interconnects 144, it is understood the structural relationships apply to other isolation trench and via arrangements within the cap substrate. As shown in FIG. 6A, the BEOL process sequence can begin with the planarized surface 135, followed by an outgassing operation and deposition of the hydrogen barrier layer 152, for example with physical vapor sputtering or with a CVD process which introduces as little hydrogen as possible, to reduce subsequent out-gassing. As shown in FIG. 6B, the hydrogen barrier layer 152 is formed directly on the planarized surface 135 including the top side 138 of the cap substrate, top side 146 of the liner layer 140, and top side 148 of the optional filler material 142. This may be followed by deposition of an optional hydrogen permeable passivation layer 154, such as silicon oxide as shown in FIG. 6C, followed by etching of openings 168 as shown in FIG. 6D to expose via interconnects 144 without exposing the isolation trenches 134. Electrical contact terminals 156 are then formed to make direct contact with the via interconnects 144, and to at least partially fill the openings 168. The electrical contact terminals 156 can include one or more layers. In the embodiment illustrated in FIG. 6E the electrical contact terminal 156 includes a first liner layer 170, such as polysilicon or any other metal seed layer, and one or more bulk metal layers 172 such as aluminum, copper, gold, etc. One or more additional hydrogen permeable passivation layers 158, such as silicon oxide, are then formed over the hydrogen barrier layer 152, optional hydrogen permeable passivation layer 154, and electrical contact terminal 156, and patterned to form openings 174 for additional electrical connection or routing.

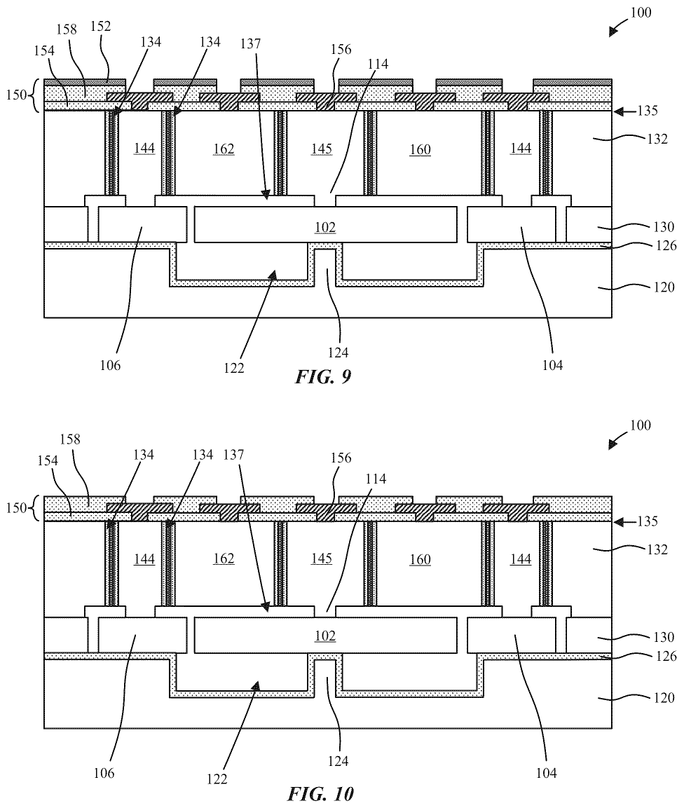

Up until this point BEOL structures have been described in which a hydrogen barrier layer 152 is formed directly on a planarized surface of the cap layer after vias reveal, or isolation trench 134 reveal, through a grinding operation. Such a configuration may avoid small molecule sources and diffusion paths from surface oxide layers. In other embodiments, hydrogen barrier layers 152 are formed at a later stage in BEOL processing, or not at all in order to avoid trapping of small molecules within the MEMS cavity and to provide an escape path for small molecules. FIGS. 7-8 are exemplary illustrations of such variations. In the particular configuration illustrated in FIG. 7, a hydrogen barrier layer 152 is formed after formation of the electrical contact terminal 156 and the hydrogen permeable passivation layer 158. In the particular configuration illustrated in FIG. 8, a hydrogen barrier layer 152 is not formed. FIGS. 9-10 are schematic cross-sectional side view illustrations of capacitively-transduced MEMS devices and cavity structures with the BEOL structures of FIGS. 7-8, respectively. In the interest of clarity and conciseness, description of similar structural relationships previously described are not repeated.

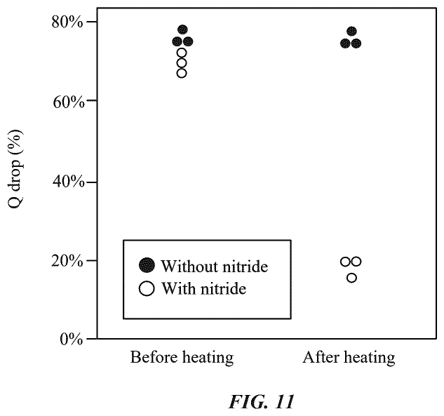

Referring now to FIG. 11, a graph is provided that illustrates experimental data of cavity pressure variation with heating inferred from resonator quality factor (Q-factor) for the MEMS devices of FIGS. 9-10, where the hydrogen barrier layer 152 is formed by plasma-enhanced chemical vapor deposition of silicon nitride. Once the MEMS devices were fabricated, cavity pressure at time zero was inferred through the Q-factor of the MEMS devices tested. The MEMS devices were then baked in an oven at 260° C. for 2 hours, and the Q-factor was then measured again, with cavity pressure increase inferred with Q-factor drop. The experimental data shows that where a silicon nitride hydrogen barrier layer is present as a top-most film, that cavity pressure may increase when the MEMS devices are heated (i.e. when sufficient energy is provided to small molecules to solid-state diffuse through the isolation trench oxide liner layer), resulting in a drop of Q-factor. Conversely, if a hydrogen barrier layer is not present as the top-most film, then cavity pressure is unaffected by heating and the Q-factor is not changed, which suggests absence of the hydrogen barrier layer as a top-most film allows small molecule escape from the cavity.

Until this point BEOL structures have been described and illustrated with regard to the potential for small molecule diffusion through the isolation trenches into the cavity, and various BEOL structures including barriers or escape paths for small molecule diffusion. In the following embodiments hydrogen barrier layers are described with regard to a bottom side of the isolation trenches, with a focus not being on small molecule diffusion through the isolation trenches, but instead providing a barrier to small molecule diffusion into the MEMS cavity from the isolation trenches. Such configurations may be possible utilizing the wafer-level processes described herein.

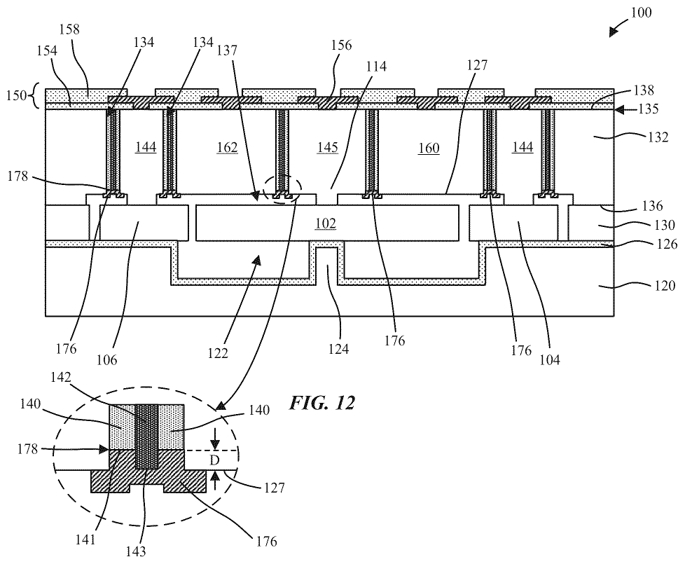

FIG. 12 is a schematic cross-sectional side view illustration of an electrostatically transduced MEMS device and cavity structure with a bottom side hydrogen barrier layer in accordance with an embodiment. In the illustrated embodiment, the MEMS device 100 includes a device layer 130 and cap substrate 132 including a bottom side 136 that is bonded to the device layer 130 and a top side 138. An upper cavity 137 is located between the device layer 130 and the cap substrate 132, and an isolation trench 134 extends through the cap substrate 132 from the top side 138 to the bottom side 136 and laterally surrounds a via of the cap substrate 132, such as a via interconnect 144, via bias electrode 145, out-of-plane via drive electrode 160, out-of-plane via sense electrode 162, etc. As shown, a hydrogen barrier layer 176 is formed on a bottom side 178 of the isolation trench 134 that faces the upper cavity 137. Referring specifically to the close-up illustration, the bottom side 178 of the isolation trench 134 can be recessed a depth (D) within the contour of the bottom side 136 of the cap substrate 132 (and specifically bottom surface 127 of recess 139 that forms the upper cavity 137), and the hydrogen barrier layer 176 may at least partially fill the recessed depth (D). In an embodiment the bottom surface 141 of the liner layer 140 may be recessed after the bulk etch operation of the expose liner layer 140. A variety of relative configurations may be possible, including the bottom side 178 being flush with the bottom surface 127 of the trench forming upper cavity 137.

The isolation trenches and vias may be arranged in a variety of locations as previously described. For example, the isolation trench can be at least partially located over a resonator element 102 of the device layer 130. As such the via may be an out-of-plane via drive electrode 160, out-of-plane via sense electrode 162, or a via bias electrode 145 including anchor 114 to provide a DC bias to the resonator element 102. The via can also be a via interconnect 144 that is bonded to an in-plane drive electrode 104 or in-plane sense electrode 106 of the device layer 130 that is laterally adjacent to the resonator element 102 (i.e. for in-plane actuation and sensing).

As shown in FIG. 12, a plurality of hydrogen barrier layers 176 can be deposited, with each hydrogen barrier layer 176 being a patch seal over a corresponding isolation trench 134. Alternatively, a large area hydrogen barrier layer 176 can be deposited over multiple isolation trenches 134 and span over the bottom side 136 of the cap substrate 132 extending therebetween. For example, a large area hydrogen barrier layer 176 can be formed over substantially the entire bottom surfaces 127 of the trenches formed in the bottom side 136 of the cap substrate 132.

The hydrogen barrier layer 176 can be formed of refractory dielectrics such as alumina, Cr2O3, TiN, TiAlN, SiN, and ZrN. Any other FEOL-compatible materials which can sustain the high-temperatures required for wafer-level packaging processes without producing by-product gases may also be utilized. Due to the proximity to the upper cavity 137, the hydrogen barrier layer 176 should be formed (including grown or deposited) using a process which minimizes the introduction of hydrogen, such as physical vapor deposition. The BEOL structure 150 of FIG. 12 may additionally be any of the BEOL structures 150 described herein and may or may not include a corresponding hydrogen barrier layer 176.

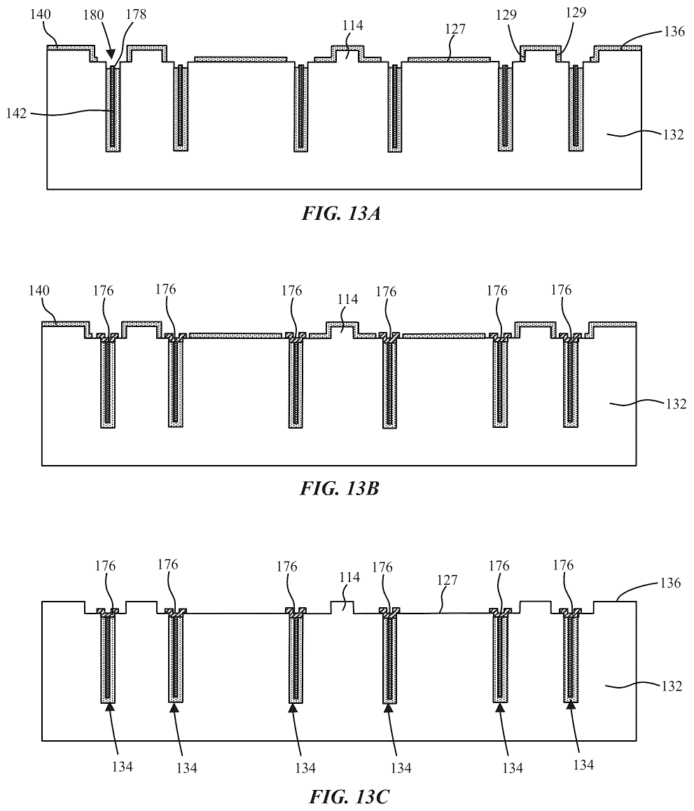

FIGS. 13A-13C are schematic cross-sectional side view illustrations of a wafer-level fabrication processes of a cap wafer including a bottom side hydrogen barrier layer in accordance with embodiments. The illustrated process flow begins with a cap substrate 132, which may be a silicon wafer, in which a patterned contour has been patterned in to bottom side 136 to include a plurality of mesas, inclusive of the optional anchor 114. The process sequence may be substantially similar to the sequence of FIGS. 3A-3D previously described. In the interest of clarity and conciseness, the figures and description are not repeated.

As shown in FIG. 13A openings 180 can be etched into the liner layer 140 that has been formed over the entire bottom side 136 of the cap substrate 132 to expose the individual isolation trenches 134. This etching operation may also recess the bottom sides 178 of the isolation trenches internally inside the cap substrate 132, and below a bottom side 136 (e.g., bottom surface 127) as described and illustrated with regard to FIG. 3D and FIG. 12. A bottom side hydrogen barrier layer 176 can then be deposited over, and optionally into, the openings 180, and directly on the isolation trenches 134 that may have optionally been recessed into the cap substrate 132. As shown in FIG. 13B, a plurality of hydrogen barrier layers 176 can be deposited and patterned, with each hydrogen barrier layer 176 being a patch seal over a corresponding isolation trench 134. Alternatively, a large area hydrogen barrier layer 176 can be deposited over multiple isolation trenches 134 and span over the bottom side 136 of the cap substrate 132 extending therebetween. In either case, this can then be followed by removal of any exposed liner layer 140 from the bottom side 136 of the cap substrate 132, inclusive of the trench bottom surfaces 127 and sidewalls 129 of the mesas, as shown in FIG. 13C. This partially processed cap substrate 132 can then be bonded to a device layer 130 as shown in the wafer-level process flow of FIG. 2C, and further processed as described herein.

In utilizing the various aspects of the embodiments, it would become apparent to one skilled in the art that combinations or variations of the above embodiments are possible for forming wafer-level encapsulated MEMS devices. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration. Furthermore, it is to be appreciated that the figures have been provided for illustrational purposes and may not be to scale. Also, in the interest of conciseness and reducing the total numbers of figures, a given figure may be used to illustrate the features of more than one aspect of the disclosure, and not all elements in the figure may be required for a given aspect.

What is claimed is:

1. A MEMS device comprising:
a device layer;
a cap substrate including a bottom side that is bonded to the device layer, and a top side;
a cavity between the device layer and the cap substrate;
an isolation trench that extends through the cap substrate from the top side to the bottom side, and laterally surrounds a via of the cap substrate; and
a hydrogen barrier layer on a bottom side of the isolation trench that faces the cavity.

2. The MEMS device of claim 1, wherein the isolation trench is at least partially directly over a resonator element of the device layer.

3. The MEMS device of claim 1, wherein the via is a via interconnect that is bonded to an in-plane drive electrode of the device layer, the in-plane drive electrode laterally adjacent to a resonator element of the device layer.

4. The MEMS device of claim 1, wherein the hydrogen barrier layer comprises a refractory dielectric selected from the group consisting of alumina, Cr2O3, TiN, TiAlN, SiN, and ZrN.

5. The MEMS device of claim 1, wherein a bottom side of the isolation trench is recessed a depth within a contour of the bottom side of the cap substrate, and the hydrogen barrier layer is directly on the isolation trench and at least partially fills the recessed depth.

6. The MEMS device of claim 1, wherein the top side of the cap substrate and a top side of the isolation trench form a planarized surface.

7. The MEMS device of claim 6, further comprising a silicon oxide layer directly on the planarized surface forming the top side of the cap substrate and the top side of the isolation trench.

8. The MEMS device of claim 6, further comprising a top hydrogen barrier layer directly on the planarized surface forming the top side of the cap substrate and the top side of the isolation trench.

9. The MEMS device of claim 1, wherein the isolation trench includes a silicon oxide liner layer and a conformal filler material.

10. A MEMS device comprising:
a device layer;
a cap substrate including a bottom side that is bonded to the device layer, and a top side;
a cavity between the device layer and the cap substrate;
an isolation trench that extends through the cap substrate from the top side to the bottom side, and laterally surrounds a via of the cap substrate;
wherein the top side of the cap substrate and a top side of the isolation trench form a planarized surface; and
a hydrogen barrier layer directly on the planarized surface forming the top side of the cap substrate and the top side of the isolation trench.

11. The MEMS device of claim 10, wherein the hydrogen barrier layer comprises a material selected from the group consisting of aluminum, copper, titanium, nickel, gold, chromium, molybdenum, titanium nitride, metal silicide, polysilicon, silicon nitride, aluminum nitride, aluminum oxide, and silicon carbide.

12. The MEMS device of claim 10, wherein the hydrogen barrier layer comprises a material selected from the group consisting of silicon nitride, aluminum nitride, aluminum oxide, and silicon carbide.

13. The MEMS device of claim 10, further comprising:
an opening in the hydrogen barrier layer that exposes the via;
an electrical contact terminal within the opening an in direct contact with the via; and
a hydrogen-permeable passivation layer directly on top of the electrical contact terminal and over the hydrogen barrier layer.

14. The MEMS device of claim 10, wherein the isolation trench is directly over a resonator element of the device layer.

15. The MEMS device of claim 10, wherein the via is a via interconnect that is bonded to a an in-plane drive electrode of the device layer, the in-plane drive electrode laterally adjacent to a resonator element of the device layer.

16. A MEMS device comprising:
a device layer;
a cap substrate including a bottom side that is bonded to the device layer, and a top side;
a cavity between the device layer and the cap substrate;
an isolation trench that extends through the cap substrate from the top side to the bottom side, and laterally surrounds a via of the cap substrate;
wherein the top side of the cap substrate and a top side of the isolation trench form a planarized surface;
a first hydrogen-permeable dielectric layer directly on the planarized surface forming the top side of the cap substrate and the top side of the isolation trench;
an opening in the first hydrogen-permeable dielectric layer that exposes the via;
an electrical contact terminal within the opening an in direct contact with the via; and
a second hydrogen-permeable dielectric layer directly on top of the electrical contact terminal and the first hydrogen-permeable dielectric layer.

17. The MEMS device of claim 16, wherein the isolation trench is at least partially directly over a resonator element of the device layer.

18. The MEMS device of claim 17, wherein the via is bonded to the resonator element.

19. A wafer-level MEMS fabrication process comprising:
patterning a support wafer to form a plurality of cavities and a plurality of anchors;
bonding a device wafer to the support wafer;
patterning the device wafer to include a plurality of resonator elements over the plurality of anchors, and plurality of electrodes laterally adjacent to the plurality of resonator elements;
bonding a cap wafer directly to the device wafer, the cap wafer including a plurality of isolation trenches extending partially through a thickness of the cap wafer and defining a corresponding plurality of vias; and
reducing a thickness of the cap wafer to expose the plurality of isolation trenches.

20. The wafer-level MEMS fabrication process of claim 19, further comprising depositing a hydrogen barrier layer directly on a planarized surface of a top side of the cap wafer and top sides of the plurality of isolation trenches.

21. The wafer-level MEMS fabrication process of claim 20, wherein depositing the hydrogen barrier layer comprises either physical vapor sputtering in a hydrogen-free environment or chemical vapor deposition.

22. The wafer-level MEMS fabrication process of claim 19, further comprising depositing a hydrogen-permeable dielectric layer directly on a planarized surface of a top side of the cap wafer and top sides of the plurality of isolation trenches.
